(19) United States
(12) Patent Application Publication
(10) Pub. No.: US 2012/0255611 A1
(43) Pub. Date: Oct. 11, 2012

(54) SOLAR MODULE AND COEXTRUDATE ELEMENT

(76) Inventor: Guenther MIKATS, Hirm (AT)

(21) Appl. No.: 13/482,212

(22) Filed: May 29, 2012

Related U.S. Application Data
(63) Continuation of application No. PCT/AT2010/000463, filed on Nov. 30, 2010.

(30) Foreign Application Priority Data
Dec. 1, 2009 (AT) A 1898/2009

(51) Int. Cl. H01L 31/0203; B32B 27/36

(52) U.S. Cl. 136/259; 428/475.2

(57) ABSTRACT

The invention relates to a solar module having at least one solar cell, which is arranged between a front cover and a rear cover, and the front cover enables the passage of light to the solar cell. The solar module includes a rear cover having an at least two-layer, halogen-free coextrudate element which has a first thermoplastic layer facing the solar cell and a second thermoplastic layer facing away from the solar cell. The first thermoplastic layer includes a first filling material, which has a reflectivity that is higher than the reflectivity of the thermoplastic of the first thermoplastic layer, and the second thermoplastic layer includes a second filling material which has a higher thermal conductivity than the thermoplastic of the second thermoplastic layer.

The invention concerns a solar module having at least one solar cell arranged between a front cover and a rear cover, wherein the front cover permits the passage of light to the solar cell.

The invention further concerns a coextrudate element including at least two thermoplastic layers and fillers.

Solar or photovoltaic modules generally have a solar cell arranged between a front cover and a rear cover. Industrially silicon-based solar cells are the most significant at the present time although other materials are increasingly being used. The front cover generally comprises translucent glass and is connected to the solar cell by way of a bonding agent comprising ethylene vinyl acetate (EVA). The rear cover (often also referred to as the backsheet film) generally comprises a fluoropolymer-based plastic film as fluoropolymers are highly temperature-resistant. By way of example attention is directed to Roekens und Beyer, Kunststoffe 5/2007 (pages 92-95), where a rear cover comprises a three-layer laminate of polyvinyl fluoride (PVF)— polyethylene terephthalate (PET)—PVF. A disadvantage in the state of the art in accordance with Roekens und Beyer is the fact that, because of the fluorine content of the rear cover, recycling thereof is possible only thermally, that is to say by means of complicated and expensive incineration processes.

JP 2007-177136 A discloses an arrangement comprising a solar cell and a backsheet film, wherein the film can contain glass fibers, mica, wollastonite or titanium dioxide. The disadvantage is that the properties of that film are substantially unchanged over the entire region and thus there is no adaptation of the property in relation to the proximity to the solar cells. In addition as a result the consumption of material of the individual fillers over the entire thickness of the backsheet film is very great. Those disadvantages also apply in a similar fashion to US 2008/0264484 A1.

EP 2 043 162 A2 describes a solar module having a front cover and a rear cover of plastic. The structure described therein is admittedly suitable for small-area applications with overall low power levels, but in the case of large-area applications in which naturally high temperatures occur, the structure disclosed therein is not suitable. U.S. Pat. No. 6,521,825 B1 discloses solar modules with rear covers comprising multi-layer plastic.

The object of the present invention is to provide a solar module or a plastic body in the form of a coextrudate element for the rear cover of a solar module, where the described disadvantages are alleviated.

In a solar module comprising at least one solar cell arranged between a front cover and a rear cover, wherein the front cover permits the passage of light to the solar cell, that object is attained in that the rear cover includes an at least two-layer halogen-free coextrudate element which has a first thermoplastic layer towards the solar cell and a second thermoplastic layer away from the solar cell, wherein the first thermoplastic layer includes a first filler which has a reflectivity which is higher than the reflectivity of the thermoplastic material of the first thermoplastic layer and the second thermoplastic layer includes a second filler which has a higher thermal conductivity than the thermoplastic material of the second thermoplastic layer, wherein in the two thermoplastic layers the proportion at least of the first filler and/or the second filler is different from the proportion of the same filler in the other thermoplastic layer. In other words this means that the first thermoplastic layer is different from the second thermoplastic layer in respect of the first filler and/or second filler.

The increase in reflectivity in the first thermoplastic layer performs two functions. On the one hand more light is incident on the solar cells as for example light passing through the solar cell or moving past the solar cell is reflected back on to the solar cell so that the yield of electromagnetic radiation converted into electric energy is increased. On the other hand the parts of the solar module, that are behind the first thermoplastic layer, are protected from thermal energy.

Due to the increase in thermal conductivity in the second thermoplastic layer by virtue of the corresponding filler the long-term temperature resistance (RTI) of the coextrudate and therewith the solar module is markedly increased. It is possible in that way to increase the power, in particular in the case of large modules where high system voltages also occur.

The solar module can be more easily produced by coextrusion.

By virtue of the larger solar modules which are now possible, and the higher system voltages linked thereto, it can advantageously be provided that the second filler additionally increases the breakdown resistance of the thermoplastic layer. Typically electric insulators which have such properties present themselves. Measurements have shown that, with a content of 20% by weight of filler in the second thermoplastic layer the breakdown resistance was improved by 12-15% (with respect to the same layer without filler). To still further increase the long-term temperature stability, it is further advantageous if the second filler additionally has a lower coefficient of thermal expansion than the thermoplastic material. As a result, this involves a lesser degree of expansion of the plastic material under a thermal loading. More specifically, in the case of simple plastic rear covers, the ongoing expansion with a rise in temperature and the subsequent contraction upon cooling have the result that the plastic layer wears out after a given number of operating hours.

Certain substances fulfil all properties, namely high thermal conductivity, high breakdown resistance and a low coefficient of thermal expansion. In particular layer-like substances like mica, for example muscovite or to a lesser degree iron mica, but also wollastonite, boron nitride or fibrous substances like glass fibers although to a lesser extent than for example mica and naturally mixtures of the said substances, can also be used. The lower coefficient of thermal expansion affords substantially less contraction whereby the embedded modules are stabilised.

The use of muscovite with a layer-like structure is preferred. In general it can be provided for layer-like substances that they are of a length and a width of between 5 and 45 μm, preferably between 5 and 15 ρm, with a thickness of less than 2 μm, preferably less than 1 μm.

It is particularly desirable in that respect if the second filler is in the form of a compound with a polyolefin, that is to say it is mixed prior to introduction into the thermoplastic layer with a polyolefin as a carrier. The subsequent introduction into thermoplastic materials provides that thermal conductivity and thus heat dissipation is improved and electric resistance is not reduced. Especially glass fibers can thus be used as a filler in the form of a compound, to good effect. In addition the polyolefin provides for a lower degree of water vapor permeability for the layer. U.S. Pat. No. 6,521,825 B1 is also concerned with reducing water vapor permeability. For that purpose a silitium oxide is vapor-deposited on to a plastic layer. Subsequently the layers of the rear cover have to be applied by lamination as coextrusion of a plastic layer with the vapor-deposited oxide layer is no longer possible. In the present invention the fillers are incorporated into the layer.

The proportion of second filler, with respect to the amount of thermoplastic material, is preferably between 5 and 30% by weight, preferably between 10 and 20% by weight.

A variant provides in the second thermoplastic layer that a filler combination is introduced. In that case the degree of filling is up to 60% by weight in dependence on the density of the fillers. In that respect a desirable combination comprises wollastonite and/or muscovite with glass fibers embedded in a polyolefin (such as for example polypropylene) as a compound.

It is further provided in a particularly preferred variant that the first filler includes titanium dioxide TiO₂. TiO₂ as the first filler has the advantage that it reflects light very greatly and this involves a reflection of over 90%, preferably over 99%, with suitable admixture. The proportion of first filler, with respect to the amount of thermoplastic material, is preferably between 5 and 30% by weight.

A preferred embodiment can provide that only the first thermoplastic layer includes a first filler having a reflectivity higher than the reflectivity of the thermoplastic material of the first thermoplastic layer. In other words the first thermoplastic layer—in contrast to the second thermoplastic layer—has no filler substantially influencing thermal conductivity. It will be appreciated however that the possibility of the thermoplastic material containing various other (for example coloring) fillers should not be excluded.

Conversely a further preferred embodiment provides that only the second thermoplastic layer includes a second filler having a higher thermal conductivity than the thermoplastic material of the second thermoplastic layer. In other words the second thermoplastic layer—in contrast to the first thermoplastic layer—has no filler substantially influencing the reflectivity.

In a preferred variant it can be provided that arranged on the side of the second thermoplastic layer, that faces away from the solar cell, is a further layer having a lower reflectivity than the surface of the front cover. It is preferably provided that the further layer is a third thermoplastic layer which with the at least two other thermoplastic layers forms the coextrudate element. It can further be provided that the further layer is colored and/or has matting means. A variant of the invention can provide that the first thermoplastic layer is colored. That presents itself for example when the solar module is to be used as a facade element. It is to be noted in that respect that the solar cells are generally not arranged over the full surface area in the module and/or are of a partially translucent nature. Therefore coloring of the rear cover is also at least partially visible from the front side.

The solar cell is mostly introduced in an embedding material. The embedding material can at the same time form a connection between the solar cell and the coextrudate element and between the solar cell and the front cover so that the embedding material is in the form of a bonding agent. The bonding agent can include for example EVA (ethylene vinyl acetate). It will be noted however that alternative bonding agents are advantageous as handling of EVA is complicated and expensive. Particularly preferably it is therefore provided that the bonding agent is a copolymer of monomer units of olefins, acrylates and maleic acid anhydride. Preferably the olefin is ethene and the acrylate is an alkyl ester of acrylic acid (alkyl acrylate).

Particular preferably the copolymer is of the following structure:

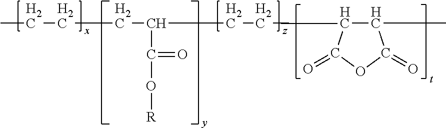

with the proviso that R=methyl (—CH₃), ethyl (—C₂H₅) or butyl (—C₄H₉) and x, y and z are whole numbers. Preferably the proportion (in each case in Md-%) of alkyl acrylate (preferably butyl acrylate) is between 15 and 20%, maleic acid anhydride between 3 and 4%, balance olefin. The copolymer preferably has a melt flow rate (MFR) at 190° C. measured in accordance with ASTM D 1238 of between 2 g/10 min and 3 g/10 min. The copolymer is preferably of a density at 20° C. of between 0.85 and 0.96 g/cm³. The Vicat softening point in accordance with ASTM D 1525 is preferably between 62 and 74° C. For good miscibility the processing temperature of the copolymer is at 270° C. In the finished condition the bonding agent with the embedded solar cells forms its own layer in the coextrudate element. In that respect the thickness of that layer is preferably between 50 μm and 400 μm.

As already mentioned in the opening part of this specification, all thermoplastic materials are fluorine-free thermoplastics. In view of temperature stability polyesters and polyamides are favorable. It will be noted however that polyamides have particularly high stability. It is therefore preferably provided that at least one thermoplastic Slayer is a polyamide layer, preferably polyamide 11, polyamide 12, polyamide 1010 or optionally a blend of those polyamides or a polyamide/polyolefin blend. All thermoplastic layers are particularly preferably formed from polyamide. Once again polyamide 11, polyamide 12, polyamide 1010 or similar polyamide types are preferably provided.

The above-mentioned coextrudate element is naturally also suitable for being produced separately and then applied to the solar cell. In a further aspect therefore the invention concerns a coextrudate element including a first thermoplastic layer having a filler having a reflectivity higher than the reflectivity of the thermoplastic material and a second thermoplastic layer including a filler having higher thermal conductivity than the thermoplastic material, wherein the thermoplastic materials are selected from the group of polyamides, polyolefins, polyesters or blends of polyamides and polyolefins (like polypropylene).

In particular mica such as muscovite or iron mica or also wollastonite, boron nitride or glass fibers and mixtures thereof prove to be advantageous as a second filler for the second thermoplastic layer. In particular, by virtue of their layer structure, micas have on the one hand a high stabilising action while on the other hand the breakdown resistance is increased and thermal conductivity advantageously influenced. In addition to the filler which increases reflectivity the first thermoplastic layer can also have the second filler which increases thermal conductivity, up to a content of 20% by weight.

Preferred layer thicknesses are between 25 μm and 50 μm for the first thermoplastic layer, between 150 μm and 400 μm for the second thermoplastic layer and between 25 μm and 50 μm for the third thermoplastic layer.

It will be appreciated that the described coextrudate elements are used in the aforementioned solar modules. Overall it is to be noted that this equally applies in turn to the coextrudate elements and solar modules, that is to say advantageous embodiments of the one are equally advantageous embodiments of the other.

The invention further concerns the use of coextrudate elements of the aforementioned kind for the production of solar modules.

Further advantages and details will be described by means of the specific description and the accompanying Figures in which, in each case in roughly diagrammatic form:

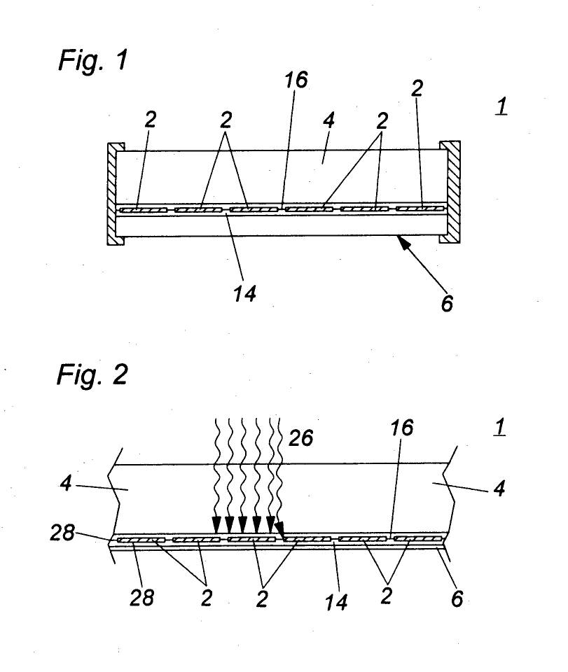

FIG. 1 shows a cross-section through a solar module according to the state of the art,

FIG. 2 diagrammatically shows the mode of operation of a solar module,

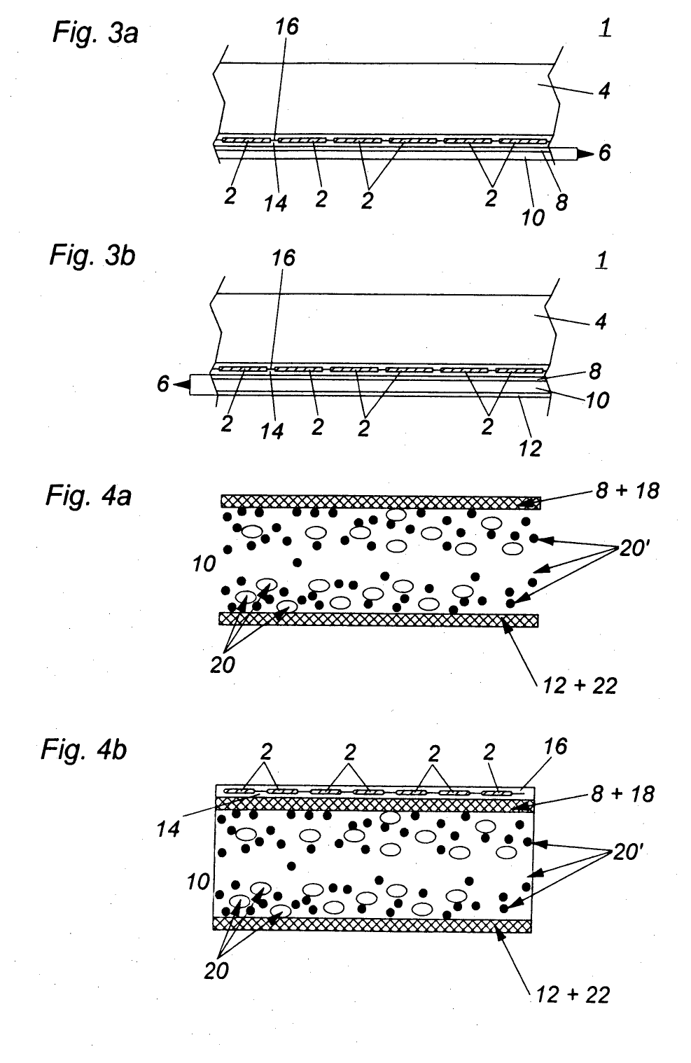

FIGS. 3a and 3b show two variants of solar modules according to the invention, and

FIGS. 4a and 4b show variants of the coextrudate element.

FIG. 1 diagrammatically shows a solar module 1 in accordance with the state of the art. This arrangement has a plurality of electrically conductingly interconnected solar cells 2 arranged between a front cover 2 and a rear cover 6. The front cover 4 is made from glass or possibly transparent plastic. The solar cells 2 are embedded in an embedding material 14, 16. The embedding material 14, 16 serves at the same time as a bonding agent layer 14, 16 and comprises EVA. EVA produces a join between the front cover 4 and the solar cells 2 (shown as a bonding agent layer 16) while the EVA also makes a join between the rear cover 6 and the solar cell 2 (shown as a bonding agent layer 14). The rear cover 6 is made from a fluoropolymer. That generally involves PVF or possibly also polyvinylidene fluoride PVDF. Such fluorine materials are highly temperature-stable but suffer from the disadvantage that they can only be recycled with very great effort. In addition the solar module has a frame 24 which facilitates fixing to a roof or a facade.

The mode of operation of solar modules generally is described with reference to FIG. 2. The solar cells 2, more precisely the photovoltaic cells, are electric components which directly convert short-wave radiation energy, that is to say for example sunlight, into electric energy. The physical basis of that conversion is the photovoltaic effect which represents a special case of the internal photoelectric effect. The solar cells 2 generally include semiconductors, for example silicon-based.

Incident light 26 is incident on the front cover 4 which is translucent, that is to say which allows a large part of the light spectrum which is advantageous for the solar cell, preferably over 90% transmission, to pass therethrough. The electromagnetic radiation is converted into electric energy by the photovoltaic effect. The individual solar cells 2 are electrically conductingly interconnected and the electric voltage generated can be taken off by way of terminals 28 (only shown in roughly diagrammatic form).

FIG. 3a shows a first variant of the invention. In this case a solar module 1 is also formed from solar cells 2 enclosed by a front cover 4 and a rear cover 6. The solar cell 2 is embedded (on all sides) in a bonding agent 14, 16—this is in order to prevent breakage of the cells and to avoid short-circuits. In this case the front cover 4 can be for example of glass or transparent plastic. The bonding agent 14, 16 makes a join between the front cover 4 and the solar cells 2 and between the rear cover 6 and the solar cells 2. In the illustrated embodiment the rear cover 6 is in the form of a two-layer coextrudate 6′, that is to say it includes a first thermoplastic layer 8 of polyamide 11, polyamide 12 or polyamide 1010, and a second thermoplastic layer 10 also of polyamide 11, polyamide 12 or polyamide 1010. Preferably only the first thermoplastic layer 8 in this case has a filler 18 which increases the reflectivity of that layer. In specific terms, titanium dioxide is used as the first filler 18, which reflects practically all the light still incident on that layer back to the solar cell 2 whereby the light yield overall is increased. Preferably only the second thermoplastic layer 10 has a second filler 20 which has a higher thermal conductivity than the thermoplastic material. That means that heat is better dissipated and the long-term temperature resistance is increased. In specific terms the second filler used is iron mica which, by virtue of its layer structure and its nature as an electric insulator, increases the breakdown resistance. It would also be possible for example to provide a matting layer on the underside of the second layer 2. The fillers are only shown in greater detail in FIG. 4, for the sake of improved clarity of the drawing.

The embodiment in FIG. 3b shows a variant having a three-layer rear cover 6 which at the same time forms the coextrudate element 6′. As the rest of the structure corresponds to the example of FIG. 3a, reference is directed to the description already set forth in the context of the description relating to FIG. 3a and the corresponding structure is not further discussed. The additionally provided third thermoplastic layer 22 in the preferred case is also made of polyamide and has a matting means so that reflection at the rear side is reduced. That increases the comfort when fitting the solar module 1 as in that way the fitter is thus less blinded. With such a layer structure the layer 8 serves as a reflection layer with a high-shine surface, the layer 10 has the higher thermal conductivity to avoid overheating or a build-up of heat, the layer 12 is weather-resistant and UV-stable, for example by the addition of UV-stabilisers.

FIGS. 4a and 4b show coextrudate elements 6′ according to the invention, based on the FIG. 3b example. The illustrated layers therefore correspond to those in FIG. 3b so that reference can be made to the foregoing description. This layer structure involves the preferred embodiment. The first filler 18 in the first thermoplastic layer 8 of polyamide is indicated by dotting. The second filler 20, 20′ in the second thermoplastic layer 10, also of polyamide, is present in this case on the one hand as a compound and is embedded in a polyolefin carrier of PE. On the other hand there is a further filler 20′ which is introduced in pure form. The filler 20 is for example a PP compound with glass and/or iron mica, while the filler 20′ is preferably muscovite and/or wollastonite. The PP compound improves the thermal conductivity due to the glass fibers or the iron mica. A matting means 22 is contained in the third thermoplastic layer 12. The first, second and third thermoplastic layers 8, 10, 12 are in the form of the coextrudate elements 6′. The difference between FIGS. 4a and 4b is that FIG. 4b additionally has a bonding agent layer 14, 16 in which preferably solar cells are embedded. The bonding agent layer 14, 16, comprises an ethylene acrylic ester maleic acid anhydride polymer with an MFR of 2.6 g/10 min in accordance with ASTM D 1238 and a density of 0.89 g/cm³ at 20° C. In the illustrated embodiment the bonding agent layer 14, 16 is denoted by two reference numerals 14, 16 to make the Figures clearer. In actual fact in practice this advantageously involves only one layer in which the solar cells 2 are embedded, while the rear cover 6 and the front cover 4 are at the same time joined to that bonding agent layer having the solar cells 2.

A substantial difference in relation to the state of the art is in the very different thermoplastic layers 8 and 10. The thermoplastic layer 8 comprises the carrier material polyamide 12, 11 or 1010, it is very highly stabilised in relation to UV-rays, but above all it is very highly filled with TiO₂ (at least between 20 and 30%). With especially treated TiO₂ that gives a high level of UV-resistance, but above all a very high reflection of about 95% (a percentage which is substantially higher than all previously known films). That high level of reflection gives a measurable increase in the efficiency as the sunlight shines through the layers 4, the embedding material 14 and 16 respectively and the solar cells 2 which are increasingly thinner (thickness at the present time between 100 and 180 μm) and is reflected by the thermoplastic layer 8.

The second thermoplastic layer 10 is of a substantially different composition. The function of that layer is in particular to reduce the coefficients of lengthwise expansion by fillers like glass fibers. For example, with PA 12, it is reduced from between 120 and 140 (10 high minus 6/K) by in length up to 70% and transversely up to 30%. That is necessary to approach the values of the glass panel 4. As is known glass has substantially lower coefficients of expansion in comparison with thermoplastic materials. Materials involving little shrinkage prevent detachment of the backsheet film which are glued to the glass panel 4 by way of the embedding material 14 and 16 respectively.

A very important function is attributed to the fillers, especially glass. In a high level of concentration (between 20 and 30%) the long-term temperature stability is greatly increased. RTI (relative temperature index) measured at the present time is at 130 degrees. Pure PA 12, 11 or 1010 have an RTI value of between 85 and 95 degrees. Further fillers can improve the thermal conductivity and breakdown resistance specified according to the invention. The thermoplastic layer 10 is an alloy of polyamides (higher proportion) and polyolefins which predominantly contain the filler content. That alloy exhibits an improved water vapor barrier and a reduced level of water absorption in comparison with polyamides. Lower water vapor permeability allows higher voltage currents in the overall module.

It is important in regard to both layers that there are relatively high levels of filler concentration in order markedly to increase the values set forth in the claims. It is therefore highly advantageous to extrude at least two or three layers together to achieve the required and specified properties. Small filler amounts (below 5% by weight) lead to scarcely measurable changes in the material property. The required properties which act very differently cannot be implemented in one layer as the filler content or the thermoplastic alloy can be coextruded only as different extrudates, preferably on a plurality of extruders.

1. A solar module comprising at least one solar cell arranged between a front cover and a rear cover, wherein the front cover permits the passage of light to the solar cell, characterised by a rear cover which includes an at least two-layer halogen-free coextrudate element which has a first thermoplastic layer towards the solar cell and a second thermoplastic layer away from the solar cell, wherein the first thermoplastic layer includes a first filler which has a reflectivity which is higher than the reflectivity of the thermoplastic material of the first thermoplastic layer and the second thermoplastic layer includes a second filler which has a higher thermal conductivity than the thermoplastic material of the second thermoplastic layer, wherein in the two thermoplastic layers the respective proportion of the first filler or the second filler is different from the proportion of the same filler in the respective other thermoplastic layer.

2. A solar module as set forth in claim 1 characterised in that in the two thermoplastic layers the proportion at least of the first filler and the second filler is different from the proportion of the same filler in the other thermoplastic layer.

3. A solar module as set forth in claim 1 characterised in that only the first thermoplastic layer includes a first filler having a reflectivity higher than the reflectivity of the thermoplastic material of the first thermoplastic layer and/or only the second thermoplastic layer includes a second filler having a higher thermal conductivity than the thermoplastic material of the second thermoplastic layer.

4. A solar module as set forth in claim 1 characterised in that the second filler additionally increases the breakdown strength of the thermoplastic material.

5. A solar module as set forth in claim 1 characterised in that the second filler additionally has a lower coefficient of thermal expansion than the thermoplastic material.

6. A solar module as set forth in claim 1 characterised in that the second filler is laminar or fibrous.

7. A solar module as set forth in claim 1 characterised in that the second filler is selected from the group mica, preferably iron mica, wollastonite, boron nitride, glass fibers or mixtures thereof.

8. A solar module as set forth in claim 1 characterised in that the first filler includes titanium dioxide (TiO₂).

9. A solar module as set forth in claim 1 characterised in that arranged on the side of the second thermoplastic layer, that is away from the solar cell, is a further layer having a lower reflectivity than the surface of the front cover.

10. A solar module as set forth in claim 9 characterised in that the further layer is a third thermoplastic layer which with the at least two other thermoplastic layers forms the coextrudate element.

11. A solar module as set forth in claim 9 characterised in that the further layer is colored and/or has matting means and/or UV-stabilisers.

12. A solar module as set forth claim 1 characterised in that at least the first thermoplastic layer and preferably the entire coextrudate element is colored.

13. A solar module as set forth in claim 1 characterised in that the solar cell is arranged in an embedding material.

14. A solar module as set forth in claim 13 characterised in that the embedding material is joined to the first thermoplastic layer and the second thermoplastic layer.

15. A solar module as set forth in claim 14 characterised in that the embedding material is a bonding agent between the first thermoplastic layer, the second thermoplastic layer and the solar cell.

16. A solar module as set forth in claim 15 characterised in that the bonding agent is a copolymer comprising the monomer units olefin, preferably ethene, acrylate, preferably alkyl acrylate and maleic acid anhydride.

17. A solar module as set forth in claim 1 characterised in that the thermoplastic materials of the first thermoplastic layer, the second thermoplastic layer and optionally the third thermoplastic layer are selected from the group of polyamides, polyesters or blends of polyamide and polyolefin.

18. A solar module as set forth in claim 17 characterised in that at least one thermoplastic material is selected from the group PA 11, PA 12, PA 1010 or blends thereof or blends with polyolefin.

19. A solar module as set forth in claim 1 characterised in that the content of first filler with respect to the first thermoplastic layer is between 5% by weight and 30% by weight.

20. A solar module as set forth in claim 1 characterised in that the content of second filler with respect to the second thermoplastic layer is between 5% by weight and 70% by weight.

21. A coextrudate element including a first thermoplastic layer with a filler having a reflectivity higher than the reflectivity of the thermoplastic material of the first thermoplastic layer and a second thermoplastic layer including a filler having a higher thermal conductivity than the thermoplastic material of the second thermoplastic layer, wherein in the two thermoplastic layers the respective proportion of the first filler or the second filler is different from the proportion of the same filler in the respective other thermoplastic layer, and wherein the thermoplastic materials are selected from the group of polyamides, polyesters or blends of polyamides and polyolefins.

22. A coextrudate element as set forth in claim 21 characterised in that there is provided a third thermoplastic layer arranged on the second thermoplastic layer.

23. A coextrudate element as set forth in claim 22 characterised in that the third thermoplastic layer is also coextruded and is additionally colored and/or has a matting means and/or an UV-stabiliser.

24. A coextrudate element as set forth in claim 21 characterised in that the first filler includes titanium dioxide.

25. A coextrudate element as set forth in claim 21 characterised in that fillers are laminar or fibrous.

26. A coextrudate element as set forth in claim 21 characterised in that the second filler is selected from the group of muscovite, wollastonite, boron nitride, iron mica, glass fibers embedded in polyolefin, or mixtures thereof.

27. A coextrudate element as set forth in claim 21 characterised in that a bonding agent is arranged on the first thermoplastic layer.

28. A coextrudate element as set forth in claim 27 characterised in that the bonding agent is a copolymer comprising the monomer units olefin, preferably ethene, acrylate, preferably alkyl acrylate, and maleic acid anhydride.

29. A facade element including a solar module as set forth in claim 1.
